(19) United States
(12) Patent Application Publication
(10) Pub. No.: US 2016/0284791 A1
(43) Pub. Date: Sep. 29, 2016

(54) CAPACITOR AND SEMICONDUCTOR DEVICE INCLUDING THE SAME

(71) Applicant: SK hynix Inc., Gyeonggi-do (KR)

(72) Inventor: Yi-Jung JUNG, Gyeonggi-do (KR)

(21) Appl. No.: 14/796,955

(22) Filed: Jul. 10, 2015

(30) Foreign Application Priority Data
Mar. 23, 2015 (KR) 10-2015-0039950

(51) Int. Cl. H01L 49/02; H01G 4/012; H01L 23/522

(52) U.S. Cl. CPC H01L 28/60; H01L 23/5226; H01G 4/012

(57) ABSTRACT

A capacitor having a capacitance that is required by a device within a limited area. The capacitor may include: a first electrode, an insulation layer, and a second electrode, wherein the first electrode may include a plurality of first vertical electrodes and a plurality of first horizontal electrodes, wherein the plurality of first vertical electrodes are spaced apart from one another by a predetermined distance in a first direction and a second direction perpendicular to the first direction, wherein the plurality of first horizontal electrodes extend in a third direction obliquely crossing with the first direction and are connected with the plurality of first vertical electrodes disposed in the third direction, wherein the second electrode may include a plurality of second vertical electrodes and a plurality of second horizontal electrodes, wherein the plurality of second vertical electrodes are disposed between the plurality of first vertical electrodes in the first direction and the second direction, wherein the plurality of second horizontal electrodes extend in the third direction and are connected with the plurality of second vertical electrodes disposed in the third direction, and wherein the plurality of first vertical electrodes and the plurality of second vertical electrodes may pass through the insulation layer.

### CROSS-REFERENCE TO RELATED APPLICATION

The present application claims priority of Korean Patent Application No. 10-2015-0039950, filed on Mar. 23, 2015, which is herein incorporated by reference in its entirety.

### BACKGROUND

The present invention relates to a semiconductor device manufacturing technology, and more particularly, to a capacitor and a semiconductor device including the same.

Due to recently developed digital media devices, a life environment is being changed such that anyone may conveniently use desired information anytime and anywhere. In step with such a trend, there is a growing interest in the field of a system-on-chip (SoC) technology, resulting in semiconductor manufacturers competing to strengthen SoC-based technology. In SoC, system technologies are integrated into one semiconductor, Therefore, without strong system design technology, it may be difficult to develop non-memory semiconductors.

Recently, a chip performing various functions, in which a digital circuit and an analog circuit are combined, has attracted attention in the field of SoC where complex technologies are integrated. To produce a chip that performs complex functions, a capacitor having various capacitances is necessary, It is increasingly difficult to obtain a capacitance required by a device within a limited area since a unit chip size gradually shrinks. Additionally, the shape of an area in which the capacitor is formed may be irregular due to the shape of a circuit around the capacitor being irregular. Therefore, it is even more difficult to realize a capacitance required by the device within a limited area having an irregular shape.

### SUMMARY

Various embodiments are directed to a capacitor having a capacitance that is required by a device within a limited area and a semiconductor device including the same.

In an embodiment, a capacitor may include: a first electrode, an insulation layer, and a second electrode wherein the first electrode may include a plurality of first vertical electrodes and a plurality of first horizontal electrodes, wherein the plurality of first vertical electrodes are spaced apart from one another by a predetermined distance in a first direction and a second direction perpendicular to the first direction, wherein the plurality of first horizontal electrodes extend in a third direction obliquely crossing with the first direction and are connected with the plurality of first vertical electrodes disposed in the third direction, wherein the second electrode may include a plurality of second vertical electrodes and a plurality of second horizontal electrodes, wherein the plurality of second vertical electrodes are disposed between the plurality of first vertical electrodes in the first direction and the second direction, wherein the plurality of second horizontal electrodes extend in the third direction and are connected with the plurality of second vertical electrodes disposed in the third direction, and wherein the plurality of first vertical electrodes and the plurality of second vertical electrodes may pass through the insulation layer.

The first electrode may include a first common electrode which is connected with the plurality of first horizontal electrodes, and wherein the second electrode may include a second common electrode which is connected with the plurality of second horizontal electrodes. The plurality of first vertical electrodes and the plurality of second vertical electrodes may be alternately disposed in the first direction and in the second direction. Each of the plurality of first vertical electrodes and the plurality of second vertical electrodes may have a square pillar shape or a rectangular pillar shape. The plurality of first horizontal electrodes and the plurality of second horizontal electrodes may be disposed in a fourth direction perpendicular to the third direction. The plurality of first horizontal electrodes and the plurality of second horizontal electrodes may be positioned under the insulation layer or over the insulation layer, The plurality of first horizontal electrodes may be positioned under the insulation layer, and wherein the plurality of second horizontal electrodes may be positioned over or under the insulation layer.

In an embodiment, a semiconductor device may include: a substrate having a first region and a second region; a multi-layered interlayer insulation layer formed over the substrate; a capacitor including a plurality vertical electrodes and formed in the first region and pass through the multi-layered interlayer insulation layer; and a multi-layered wiring structure formed in the multi-layered interlayer insulation layer in the second region.

The plurality vertical electrodes of the capacitor may include: a first electrode may include a plurality of first vertical electrodes, a plurality of first horizontal electrodes, and a first common electrode, and a second electrode may include a plurality of second vertical electrodes, a plurality of second horizontal electrodes, and a second common electrode, wherein the plurality of first vertical electrodes are spaced apart from one another by a predetermined distance in a first direction and a second direction perpendicular to the first direction, and pass through partially or completely the multi-layered interlayer insulation layer, wherein the plurality of first horizontal electrodes extend in a third direction obliquely crossing with the first direction and are connected with the plurality of first vertical electrodes disposed in the third direction, wherein the first common electrode is connected with the plurality of first horizontal electrodes, wherein the plurality of second vertical electrodes are disposed between the plurality of first vertical electrodes in the first direction and the second direction and pass through partially or completely the multi-layered interlayer insulation layer, wherein the plurality of second horizontal electrodes extend in the third direction and are connected with the plurality of second vertical electrodes disposed in the third direction, and wherein the second common electrode is connected with the plurality of second horizontal electrodes.

The plurality of first vertical electrodes and the plurality of second vertical electrodes may be alternately disposed in the first direction and the second direction. Each of the plurality of first vertical electrodes and the plurality of second vertical electrodes may have a square pillar shape or a rectangular pillar shape. The plurality of first horizontal electrodes and the plurality of second horizontal electrodes may be disposed in a fourth direction perpendicular to the third direction.

According to the embodiments since the capacitor includes a plurality of vertical electrodes which pass through an insulation layer or a multi-layered interlayer insulation layer, a capacitance required by a device within a limited area may be realized, and the capacitor may be efficiently realized even within a space having an irregular shape. Also, since the capacitor may be realized through an existing line forming process without a separate additional process, process compatibility and productivity may be improved.

### BRIEF DESCRIPTION OF THE DRAWINGS

FIG. 1 is a plan view illustrating a capacitor in accordance with an embodiment.

FIG. 2 is a plan view illustrating a modified example of the capacitor in accordance with the embodiment.

FIG. 3 is a view illustrating the cross-section taken along the line A-A′ of FIG. 1.

FIG. 4 is a view illustrating a cross-section of a capacitor in accordance with an embodiment.

FIG. 5 is a cross-sectional view schematically illustrating a semiconductor device including a capacitor in accordance with an embodiment.

FIG. 6 is a block diagram illustrating a memory card.

FIG. 7 is a block diagram illustrating an electronic system.

### DETAILED DESCRIPTION

Various examples and implementations of the disclosed technology are described below in detail with reference to the accompanying drawings.

The drawings may not be necessarily to scale and in some instances, proportions of at least some of structures in the drawings may have been exaggerated to clearly illustrate certain features of the described examples or implementations. In presenting a specific example in a drawing or description having two or more layers in a layer structure, the relative positioning relationship of such layers or the sequence of disposing the layers as shown reflects a particular implementation for the described or illustrated example and a different relative positioning relationship or sequence of disposing the layers may be possible, In addition, a described or illustrated example of a multi-layer structure may not reflect all layers present in that particular multilayer structure, for example, one or more additional layers may be present between two illustrated layers. As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

Embodiments to be described below provide a capacitor capable of providing a capacitance that is required by a device within a limited area, and a semiconductor device including the same. The limited area may mean that a physical space provided for the capacitor is small. In addition, the limited area may mean that the space provided for the capacitor has an irregular shape, rather than a square or rectangular shape.

To this end, a capacitor according an embodiment may be a capacitor including a first electrode, an insulation layer, and a second electrode. Each of the first electrode and the second electrode may include a plurality of vertical electrodes passing through the insulation layer, a plurality of horizontal electrodes connected with the plurality of vertical electrodes, and a common electrode connected with the plurality of horizontal electrodes. By including the plurality of vertical electrodes passing through the insulation layer, a capacitance required by a device within a limited area may be realized, and it is possible to effectively realize the capacitor within a space having an irregular shape. Moreover, since the capacitor may be realized through an existing line-forming process without adding a separate process, a fabrication process is not complicated.

In the following embodiments, a metal-oxide-metal (MOM) capacitor will be described as an example. Generally, a MOM capacitor uses a plurality of lines disposed densely and an interlayer insulation layer, as electrodes and a dielectric layer, respectively, and has 1 or 2 electrodes for example, bottom electrodes or top electrodes.

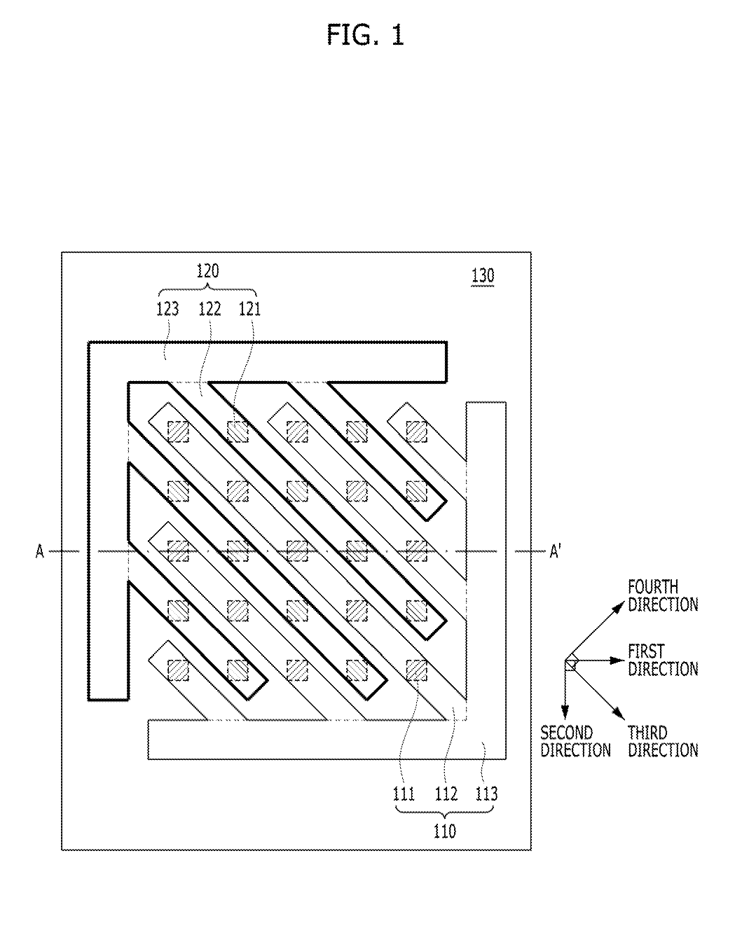

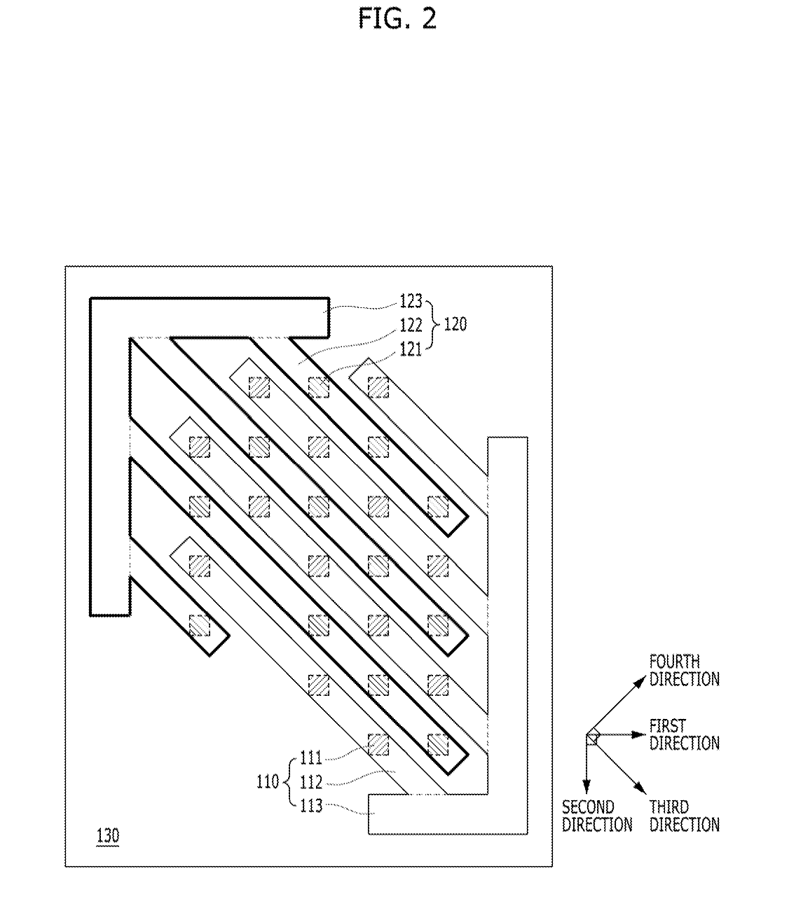

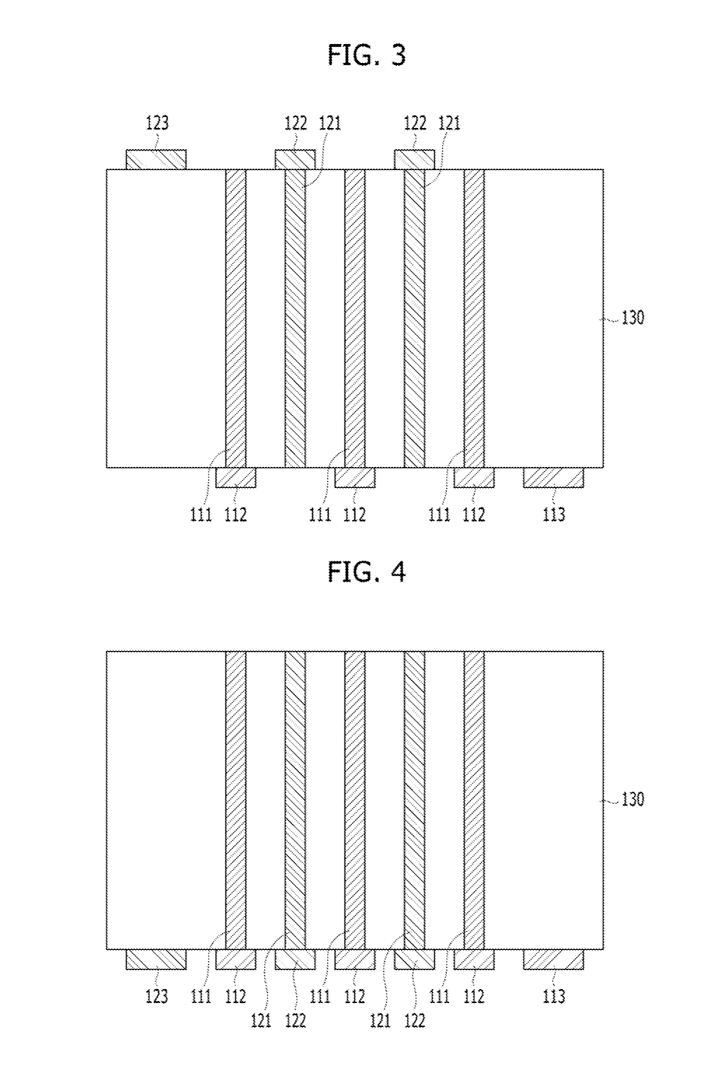

FIG. 1 is a plan view illustrating a capacitor in accordance with an embodiment, and FIG. 2 is a plan view illustrating a modified example of the capacitor in accordance with the embodiment. FIG. 3 is a view illustrating the cross-section taken along the line A-A′ of FIG. 1, FIG. 4 is a view illustrating a cross-section of a capacitor in accordance with an embodiment.

As illustrated in FIGS. 1 to 4, a capacitor according to an embodiment may include a first electrode 110, an insulation layer 130, and a second electrode 120. The insulation layer 130 may serve as the dielectric layer of the capacitor, and the first electrode 110 and the second electrode 120 may respectively serve as a bottom electrode and a top electrode.

The first electrode 110 may include a plurality of first vertical electrodes 111, one or more first horizontal electrodes 112, and a first common electrode 113. The second electrode 120 may include a plurality of second vertical electrodes 121, one or more second horizontal electrodes 122, and a second common electrode 123.

The first electrode 110 and the second electrode 120 may include a metallic material. The insulation layer 130 may include an oxide layer, a nitride layer, an oxynitride layer, or a multi-layer thereof.

The plurality of first vertical electrodes 111 are disposed spaced apart from one another by a predetermined distance in a first direction and a second direction perpendicular to the first direction. The plurality of first vertical electrodes 111 pass through the insulation layer 130. The plurality of first horizontal electrodes 112 extend in a third direction obliquely crossing with the first direction. The plurality of first horizontal electrodes 112 are electrically connected with the first vertical electrodes 111 and extend in the third direction. The plurality of first horizontal electrodes 112 are positioned over or under the insulation layer flow The first common electrode 113 is electrically connected with the plurality of first horizontal electrodes 112.

The plurality of second vertical electrodes 121 are spaced apart from one another by a predetermined distance in the first and second directions and pass through the insulation layer 130. That is, the second vertical electrodes 121 may be arranged in the third direction. The plurality of second horizontal electrodes 122 extend in the third direction, are electrically connected with the second vertical electrodes 121, each extending in the third direction, and are positioned over or under the insulation layer 130. The second common electrode 123 is electrically connected with the plurality of second horizontal electrodes 122.

The second vertical electrodes 121 may be disposed between the first vertical electrodes 111. That is, the plurality of first vertical electrodes 111 and the plurality of second vertical electrodes 121 may be disposed alternately in the third direction.

If a space provided for the capacitor has a regular shape such as a square or a rectangle, the plurality of first vertical electrodes 111 and the plurality of second vertical electrodes 121 may be disposed in a matrix form or a check pattern and have a uniform interval therebetween, either in the first direction or the second direction, as illustrated in FIG. 1. If a space provided for the capacitor has an irregular shape, the plurality of first vertical electrodes 111 and the plurality of second vertical electrodes 121 may be disposed in a matrix form in general, as illustrated FIG. 1, but may be disposed in an irregular manner at specific locations. as illustrated in FIG. 2 depending on a shape of the provided space. Although the space provided for the capacitor has an irregular shape, the capacitor may be easily realized by using the plurality of first vertical electrodes 111 and the plurality of second vertical electrodes 121 each passing through the insulation layer 130.

The plurality of first vertical electrodes 111 and the plurality of second vertical electrodes 121 may be alternately disposed in a matrix form in the first and second directions is to easily increase a fringe capacitance, thereby increasing the total capacitance of the capacitor. To effectively increase the fringe capacitance, each of the plurality of first vertical electrodes 111 and the plurality of second vertical electrodes 121 may be in a square pillar shape or a rectangular pillar shape to maximize a contact area with the insulation layer 130, and maximize a overlapping area the plurality of first vertical electrodes 111 and the plurality of second vertical electrodes 121. For example, each of the plurality of first vertical electrodes 111 may have four facing surfaces with respect to the plurality of second vertical electrodes 121 adjacent thereto. In a conventional MOM capacitor, each electrode has two facing surfaces with respect to its neighboring electrodes. Accordingly, a facing area at least two times larger than the conventional MOM capacitor may be secured according to an embodiment. In addition, a capacitance several times to several ten times larger than a conventional MOM capacitor may be secured.

The plurality of first horizontal electrodes 112 and the plurality of second horizontal electrodes 122 may be a line shape or a bar shape extending in the third direction. The plurality of first horizontal electrodes 112 and the plurality of second horizontal electrodes 122 may be disposed in a fourth direction perpendicular to the third direction. Such a disposition of the plurality of first horizontal electrodes 112 and the plurality of second horizontal electrodes 122 may effectively increase the total capacitance of the capacitor including the fringe capacitance when the plurality of first vertical electrodes 111 and the plurality of second vertical electrodes 121 are alternately disposed in a matrix form in the first and second directions.

The plurality of first horizontal electrodes 112 and the plurality of second horizontal electrodes 122 may be positioned at the same level or may be positioned at different levels from each other. In detail, as illustrated in FIG. 3, the plurality of first horizontal electrodes 112 may be positioned under the insulation layer 130, and the plurality of second horizontal electrodes 122 may be positioned over the insulation layer 130. In another embodiment, the plurality of first horizontal electrodes 112 and the plurality of second horizontal electrodes 122 may be positioned under the insulation layer 130 as illustrated in FIG. 4, or may be positioned over the insulation layer 130.

The first common electrode 113 and second comma electrode 123 play the role of electrically connecting the plurality of first horizontal electrodes 112 and the plurality of second horizontal electrodes 122, respectively. Thus, the plurality of first horizontal electrodes 112 and the plurality of second horizontal electrodes 123 may extend respectively from the first common electrode 113 and the second common electrode 123. The first common electrode 113 and the second common electrode 123 may serve as contact pads which connect the capacitor with an external circuit. The first common electrode 113 and the second common electrode 123 may be positioned on sides or edges of the plurality of first electrodes 111 and the plurality of second electrodes 121 which are arranged in a matrix form.

Since the capacitor having the aforementioned structure includes the plurality of first vertical electrodes 111 and the plurality of second vertical electrodes 121 which pass through the insulation layer 130, a high capacitance required by a device may be realized within a limited area and even in an irregularly shaped area.

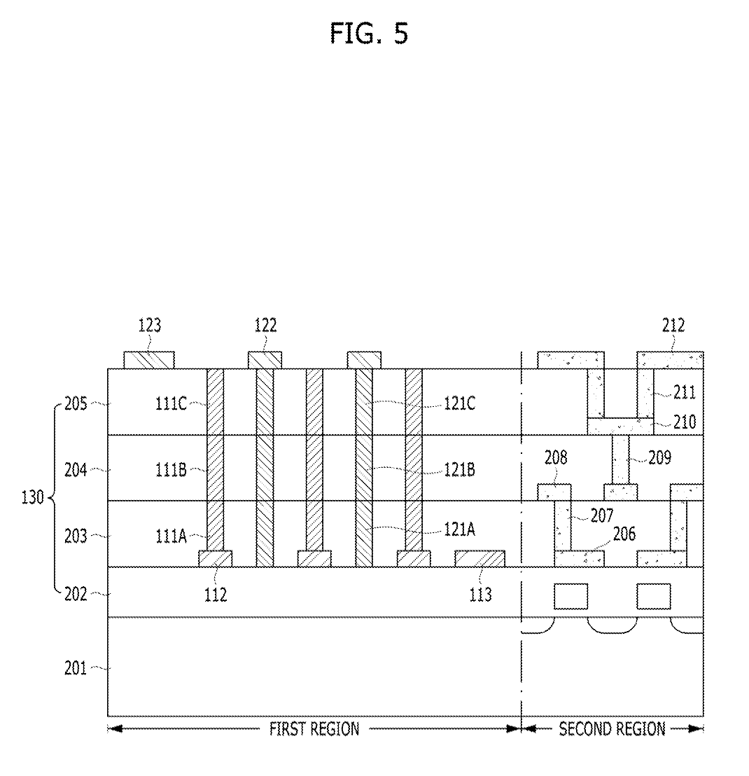

FIG. 5 is a cross-sectional view schematically illustrating a semiconductor device including a capacitor in accordance with an embodiment. For the sake of convenience in description, the same reference numerals as used in FIGS. 1 to 4 will be used for the same or like elements, and detailed descriptions thereof will be omitted.

As illustrated in FIG. 5, the semiconductor device according to the present embodiment may include a substrate 201 which has a first region and a second region, a multi-layered interlayer insulation layer 130 which is formed on the substrate 201, a capacitor including vertical electrodes 111A-111C and 121A-121C which pass through one or more layers of the multi-layered interlayer insulation layer 130 in the first region, and a multi-layered wiring structure which is formed in the multi-layered interlayer insulation layer 130 in the second region.

The multi-layered wiring structure may include multiple layers of metal lines 206, 208, 210 and 212 and plugs 207, 209 and 211 which connect the metal lines 206, 208, 210 and 212 with one another.

The first region may be a region where passive elements including the capacitor are formed, and the second region may be a device region. The device region may be a region where a memory element, an analog circuit, a digital circuit, and so forth are formed. The multi-layered interlayer insulation layer 130, which includes, for example, a first interlayer insulation layer 202 to a fourth interlayer insulation layer 205, may be formed on the substrate 201. Each of the interlayer insulation layers 202, 203, 204 and 205 may be a single layer or a multi-layer of an oxide layer, a nitride layer, an oxynitride layer, etc.

The second region may include a first interlayer insulation layer 202 which is formed on the substrate 201 and in which predetermined structures, for example, transistors are formed, first metal lines 206 which are formed on the first interlayer insulation layer 202, a second interlayer insulation layer 203 which is formed on the first interlayer insulation layer 202, second metal lines 208 which are formed on the second interlayer insulation layer 203, first plugs 207 which electrically connect the first metal lines 206 and the second metal lines 208 through the second interlayer insulation layer 203, a third interlayer insulation layer 204 which is formed on the second interlayer insulation layer 203, third metal lines 210 which are formed on the third interlayer insulation layer 204, second plugs 209 which electrically connect the second metal lines 208 and the third metal lines 210 through the third interlayer insulation layer 204, a fourth interlayer insulation layer 205 which is formed on the third interlayer insulation layer 204, fourth metal lines 212 which are formed on the fourth interlayer insulation layer 205, and third plugs 211 which electrically connect the third metal lines 210 and the fourth metal lines 212 through the fourth interlayer insulation layer 205.

The first region may include a plurality of first horizontal electrodes 112 and a first common electrode 113 which are formed on the first interlayer insulation layer 202, a plurality of first vertical electrodes 111A, 111B and 111C and a plurality of second vertical electrodes 121A, 121B and 121C which pass through the second interlayer insulation layer 203 to the fourth interlayer insulation layer 205, and a plurality of second horizontal electrodes 122 and a second common electrode 123 which are formed on the fourth interlayer insulation layer 205. The plurality of first horizontal electrodes 112 and the first common electrode 113 may be formed together with the first metal lines 206, and the plurality of second horizontal electrodes 122 and the second common electrode 123 may be formed together with the fourth metal lines 212. The plurality of first vertical electrodes 111A, 111B and 111C and the plurality of second vertical electrodes 121A, 121B and 121C may be formed together in a process for forming the first plugs 207 to the third plugs 211.

Since a capacitor may be realized through an existing line forming process without a separate additional process, process compatibility and productivity may be improved.

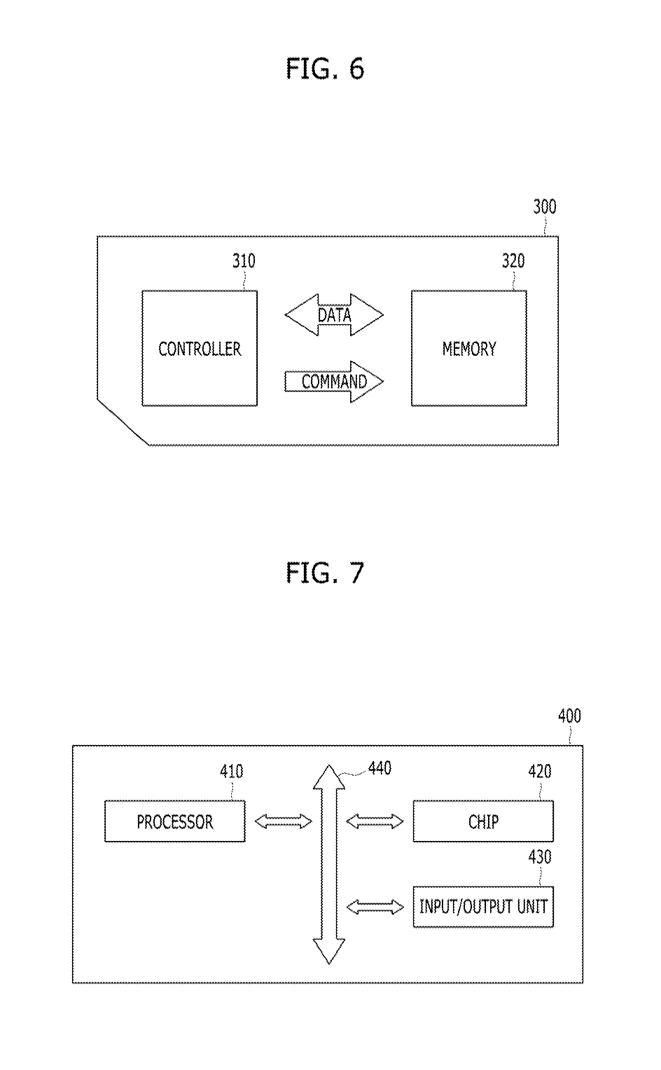

The semiconductor device according to the aforementioned embodiment may be used in various electronic devices or systems. FIGS. 6 and 7 show examples of an electronic device or a system which may be realized using the semiconductor device according to the aforementioned embodiment.

FIG, 6 is a block diagram illustrating a memory card. Referring to FIG. 6, a memory card 300 may include a controller 310 and a memory 320. The controller 310 and the memory 320 may exchange electrical signals. For example, the memory 320 and the controller 310 may exchange data according to a command from the controller 310. Accordingly, the memory card 300 may store data in the memory 320 or may output data from the memory 320 to an exterior. The memory 320 may include the semiconductor device according to the aforementioned embodiment. The memory card 300 may be used as the data storage medium of various portable appliances.

FIG. 7 is a block diagram illustrating an electronic system. Referring to FIG. 7, an electronic system 400 may include a processor 410, an input/output device 430, and a chip 420 which may perform data communication with one another through a bus 440. The processor 410 may function to execute a program and control the electronic system 400. The input/output device 430 may be used to input or output the data of the electronic system 400. The electronic system 400 may be connected with an external device, for example, a personal computer or a network, by using the input/output device 430, and may exchange data with the external device. The chip 420 may store codes or data for the operations of the processor 410, and may process a part of the operations provided from the processor 410. For example, the chip 420 may include the semiconductor device according to the aforementioned embodiment. The electronic system 400 may configure various electronic control devices that require the chip 420.

Although various embodiments have been described for illustrative purposes, it will be apparent to those skilled in the art that. various changes and modifications may be made without departing from the spirit and scope of the invention as defined in the following claims.

What is claimed is:

1. A capacitor comprising:
a first electrode, an insulation layer, and a second electrode,
wherein the first electrode includes a plurality of first vertical electrodes and a plurality of first horizontal electrodes,
wherein the plurality of first vertical electrodes are spaced apart from one another by a predetermined distance in a first direction and a second direction perpendicular to the first direction,
wherein the plurality of first horizontal electrodes extend in a third direction obliquely crossing with the first direction and are connected with the plurality of first vertical electrodes disposed in the third direction,
wherein the second electrode includes a plurality of second vertical electrodes and a plurality of second horizontal electrodes,
wherein the plurality of second vertical electrodes are disposed between the plurality of first vertical electrodes in the first direction and the second direction,
wherein the plurality of second horizontal electrodes extend in the third direction and are connected with the plurality of second vertical electrodes disposed in the third direction, and
wherein the plurality of first vertical electrodes and the plurality of second vertical electrodes pass through the insulation layer.

2. The capacitor of claim 1, wherein the first electrode includes a first common electrode which is connected with the plurality of first horizontal electrodes, and
wherein the second electrode includes a second common electrode which is connected with the plurality of second horizontal electrodes.

3. The capacitor of claim 1, wherein the plurality of first vertical electrodes and the plurality of second vertical electrodes are alternately disposed in the first direction and in the second direction.

4. The capacitor of claim 1, wherein each of the plurality of first vertical electrodes and the plurality of second vertical electrodes has a square pillar shape or a rectangular pillar shape.

6. The capacitor of claim 1, wherein the plurality of first horizontal electrodes and the plurality of second horizontal electrodes are disposed in a fourth direction perpendicular to the third direction.

6. The capacitor of claim 1 wherein the plurality of first horizontal electrodes and the plurality of second horizontal electrodes are positioned under the insulation layer or over the insulation layer.

7. The capacitor of claim 1, wherein the plurality of first horizontal electrodes are positioned under the insulation layer, and wherein the plurality of second horizontal electrodes are positioned over or under the insulation layer.

8. A semiconductor device comprising:
a substrate having a first region and a second region;
a mufti-layered interlayer insulation layer formed over the substrate;
to a capacitor including a plurality vertical electrodes and formed in the first region and pass through the multi-layered interlayer insulation layer; and
a multi-layered wiring structure formed in the multi-layered interlayer insulation layer in the second region.

9. The semiconductor device of claim 8, wherein the plurality vertical electrodes of the capacitor comprises;
a first electrode including a plurality of first vertical electrodes, a plurality of first horizontal electrodes, and a first common electrode, and
a second electrode including a plurality of second vertical electrodes, a plurality of second horizontal electrodes, and a second common electrode,
wherein the plurality o first vertical electrodes are spaced apart from one another by a predetermined distance in a first direction and a second direction perpendicular to the first direction and pass through partially or completely the multi-layered interlayer insulation layer,
wherein the plurality of first horizontal electrodes extend in a third direction obliquely crossing with the first direction and are connected with the plurality of first vertical electrodes disposed in the third direction,
wherein the first common electrode is connected with the plurality of first horizontal electrodes,
wherein the plurality of second vertical electrodes are disposed between the plurality of first vertical electrodes in the first direction and the second direction and pass through partially or completely the multi-layered interlayer insulation layer,
wherein the plurality of second horizontal electrodes extend in the third direction and are connected with the plurality of second vertical electrodes disposed in the third direction, and
wherein the second common electrode is connected with the plurality of second horizontal electrodes.

10. The semiconductor device of claim 9, wherein the plurality of first vertical electrodes and the plurality of second vertical electrodes are alternately disposed in the first direction and the second direction.

11. The semiconductor device of claim 9, wherein each of the plurality of first vertical electrodes and the plurality of second vertical electrodes has a square pillar shape or a rectangular pillar shape.

12. The semiconductor device of claim 9, wherein the plurality of first horizontal electrodes and the plurality of second horizontal electrodes are disposed in a fourth direction perpendicular to the third direction.
